(19) United States
(12) Patent Application Publication
(10) Pub. No.: US 2024/0038651 A1
(43) Pub. Date: Feb. 1, 2024

(54) CIRCUIT BOARD ARRANGEMENT

(71) Applicant: Rolls-Royce Deutschland Ltd & Co KG, Blankenfelde-Mahlow (DE)

(72) Inventors: Stanley BUCHERT, Herzogenaurach (DE); Uwe WALTRICH, Forchheim (DE)

(21) Appl. No.: 18/227,895

(22) Filed: Jul. 28, 2023

(30) Foreign Application Priority Data
Jul. 29, 2022 (DE) 10 2022 119 084.6

(51) Int. Cl. H01L 23/498; H01L 23/00; H01L 21/48; H05K 3/34

(52) U.S. Cl. CPC H01L 23/49838; H01L 24/20; H01L 21/4846; H05K 3/3436; H01L 2224/215; H01L 2224/211; H01L 2924/01029; H01L 23/3121

(57) ABSTRACT

A circuit board arrangement includes a circuit board having an upper side and an underside, and an electrical module having an upper side and an underside. The upper side of the electrical module is arranged on the underside of the circuit board. The electrical module includes a solder pad that is in electrical contact via a solder layer with an associated solder pad of the circuit board. The electrical module includes a metallization layer located at a distance from the upper side, an electrical component that is arranged on the metallization layer and is electrically connected thereto, and at least one via extending from the solder pad on the upper side of the electrical module up to the metallization layer. A solder resist is partially arranged on the solder pad such that the at least one via, applied to the solder pad, is shielded from the solder.

This application claims the benefit of German Patent Application No. DE 10 2022 119 084.6, filed on Jul. 29, 2022, which is hereby incorporated by reference in its entirety.

### BACKGROUND

The present embodiments relate to a circuit board arrangement and to a method for producing a circuit board arrangement of the type.

Ceramic circuit carriers, in which a metallization layer at high-voltage potential is formed on an insulating ceramic layer that is coupled with a heat sink directly or via further layers, are known. An example of such a circuit carrier is that of direct bonded copper (DBC) substrates. In this case, the ceramic circuit carrier, together with the semiconductor component and a sheath (e.g., made of encapsulating material), forms an electrical module that may be connected to the circuit board via contacts formed on its surface. Such modules are also referred to as prepackage modules.

Such electrical modules behave in such a way that the via required for an electrical contact from the upper side of the electrical module to the metallization layer formed on the ceramic layer is to have a substantial length or hole depth, as the via is to extend at least over the thickness of the semiconductor device. The resulting holes lead to an undefined outflow of solder in the subsequent soldering process, which may adversely affect the solder connection of the module to the carrier board and reduce its service life. Another problem is that with the outflow of solder, the holes are partially closed off, which may lead to air traps. Under the influence of temperature, such a fault may lead to the loss of the electrical contact of the via.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an electrical module that is equipped with vias that are implemented in a defined manner and without the risk of being closed off by solder is provided. As another example, a method for producing an electrical module of the type is provided.

In a first aspect of the present embodiments, a circuit board arrangement that includes a circuit board with an upper side and an underside, and at least one electrical component that is arranged on the underside of the circuit board is provided. The electrical module is located with its upper side on the lower side of the circuit board. The electrical module includes a solder pad (also referred to as a solder contact) arranged on its upper side, which is in electrical contact via a solder layer with an associated solder pad of the circuit board, a metallization layer located at a distance from the upper side, an electrical component that is arranged on the metallization layer and is electrically connected thereto, and at least one via extending from the solder pad on the upper side of the electrical module up to the metallization layer.

A solder resist is partially arranged on the solder pad such that the via, which is applied to the solder pad, is shielded from the solder.

The solution according to the present embodiments is based on the idea of arranging a solder resist on the solder pad itself, which protects or shields the vias from solder applied to the solder pad. This provides that the at least one via is protected from the ingress of solder during the production of a solder connection between the circuit board and the electrical module. This prevents an undefined solder outflow and thus provides a defined solder layer to the main board, as well as avoiding air entrapment in the via and thus the risk of damage to the circuit board.

Another advantage associated with the solution according to the present embodiments is that the use of the solder resist provides that the surface of the module has a defined state after the soldering process. This is important for a subsequent act in which a gap between the upper side of the electrical module and the underside of the circuit board is filled with an insulator, such as an epoxy resin, in an underfill process. The latter is particularly important in the case of high electric field strengths between the upper side of the electrical module and the circuit board or carrier board.

For the purposes of the present embodiments, the side of the circuit board on which the electrical module is arranged is always referred to as the underside of the circuit board, irrespective of the actual spatial orientation of the circuit board and the module.

An embodiment provides that the solder resist is arranged as a strip or thin line on the solder pad, where the strip made of solder resist extends over the entire width of the solder pad and subdivides the solder pad into two regions, a first region on which solder is applied, and a second region that is free of solder. The vias are formed in the second region. By applying a strip of solder resist, the solder pad may be divided into two regions in a simple and efficient manner. When applying solder, the solder is applied to only one region. The other region, in which the at least one via is formed, is protected from solder by the solder resist.

A further embodiment provides that the solder resist is arranged along a frame on the solder pad, which surrounds the at least one via. The frame of solder resist subdivides the solder pad into two regions, a first region to which solder is applied and a second region that is free of solder. The at least one via is formed in the second region. It may be provided that the frame surrounds a plurality of vias arranged in a row. The arrangement of the solder resist along a frame provides a particularly secure shielding of the vias from solder.

A further embodiment provides that the solder resist is formed over the entire surface of the upper side of the electrical module, with the exception of certain regions on which the surface forms the solder pad and further solder pads. The solder resist covers the solder pad in the region of the at least one via. Due to the fact that the solder resist is also applied to the vias, this configuration further increases the protection against the ingress of solder into the vias. In addition, the covering of the upper side of the electrical module with solder resist substantially over its entire surface outside the solder pads provides a defined surface.

A further embodiment provides that each individual via is individually protected from solder with solder resist, where each via is surrounded by solder resist over an angular range of 360°. For example, it may be provided that the solder resist is arranged on the solder pad in a circular manner around the respective via. Such a configuration reduces the surface area on the solder pad, which is protected against solder, so that the surface of the solder pad that may be used for soldering is maximized.

The solder pad may in principle have any desired geometrical shape. In embodiments, it is provided that the solder pad is rectangular. Further, in embodiments, it is provided that a plurality of vias that are arranged in one or more rows is provided.

A further embodiment provides that a plurality of electrical modules is arranged on the circuit board, where the electrical modules are arranged, for example, in rows. For example, the electrical modules form a plurality of logical switches of an inverter.

The electrical component integrated in the electrical module may be a semiconductor component (e.g., a power semiconductor such as a power MOSFET or an IGBT component). This is, for example, a power semiconductor of an inverter or, in general, of a power converter that is provided for the operation of an electric motor.

A further embodiment provides that the electrical module further includes a ceramic circuit carrier having an insulating ceramic layer, the metallization layer being arranged on the upper side of the ceramic layer. The electrical module further includes further solder pads that are arranged on the upper side of the electrical module and are used for contacting contacts on the upper side of the electrical component.

Further, an additional metallization layer may be provided on the underside of the ceramic layer, where via the additional metallization layer and/or a thermal interface material, a thermal connection to a heat sink is made. This type of ceramic circuit carrier provides electrical insulation of the electrical component from the heat sink and at the same time provides the thermal connection to the heat sink.

In a further aspect of the present embodiments, a method for producing a circuit board arrangement is provided. The circuit board arrangement includes a circuit board with an upper side and an underside, and an electrical module with an upper side and an underside. The electrical module is arranged with its upper side on the underside of the circuit board. The electrical module includes a solder pad arranged on its upper side, which is in electrical contact via a solder layer with an associated solder pad of the circuit board. The electrical module includes a metallization layer located at a distance from the upper side, an electrical component that is arranged on the metallization layer and is electrically connected thereto, and at least one via extending from the solder pad on the upper side of the electrical module up to the metallization layer. The method includes providing the electrical module, providing the circuit board, and applying a solder resist to the solder pad such that the solder resist protects the at least one via against the ingress of solder. The method includes applying solder to a subregion of the solder pad, and providing a solder connection between the solder pad and the associated solder pad of the circuit board. Due to the solder resist, no solder enters the via when solder is applied to the solder pad for producing the solder connection.

### BRIEF DESCRIPTION OF THE DRAWINGS

The invention will be explained in more detail below based on a plurality of embodiments with reference to the figures of the drawing. In the drawings:

FIG. 1 shows one embodiment of a circuit board arrangement having a circuit board and an electrical module;

FIG. 2 shows a plan view of an electrical module of a circuit board arrangement according to FIG. 1;

FIG. 3 shows a plan view of an electrical module of a circuit board arrangement according to FIG. 1;

FIG. 4 shows a plan view of an electrical module of a circuit board arrangement according to FIG. 1;

FIG. 5 shows a plan view of an electrical module of a circuit board arrangement according to FIG. 1; and

FIG. 6 shows a flow diagram of one embodiment of a method for producing a circuit board arrangement.

### DETAILED DESCRIPTION

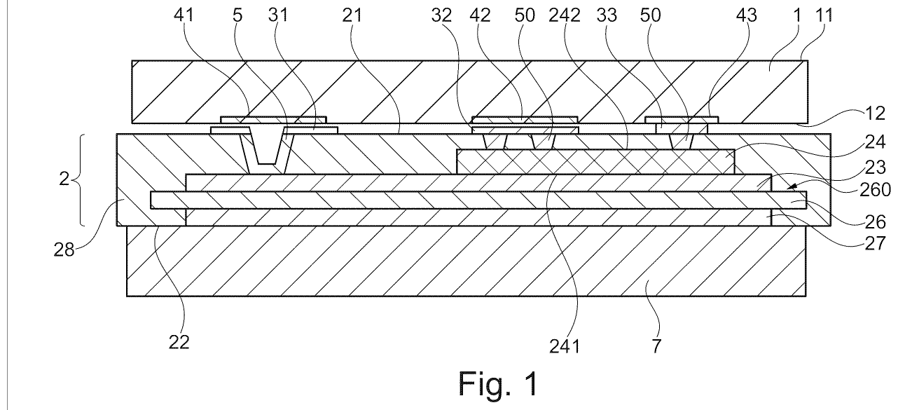

To give a better understanding of the present invention, the basic structure of a circuit board arrangement according to the present embodiments will be described first with reference to FIG. 1.

FIG. 1 shows a circuit board arrangement that includes a circuit board 1 and an electrical module 2. The circuit board 1 includes an upper side 11 and an underside 12. A plurality of solder pads 41, 42, 43 is provided on the underside 12 for contacting the electrical module 2.

The electrical module 2 has an upper side 21 and an underside 22. The electrical module 2 includes a ceramic circuit carrier 260, an electrical component 24, and electrical contacts 31, 32, 33 that are arranged on the upper side 21 of the electrical module 2. The ceramic circuit carrier 260 includes an insulating ceramic layer 26, a metallization layer 23 arranged on the upper side of the ceramic layer 26, and a further metallization layer 27 arranged on the underside of the ceramic layer 26. The ceramic layer 26 consists, for example, of aluminum nitride (AlN) or silicon nitride (Si₃N₄). The metallization layers 23, 27 consist of copper, aluminum, silver, or tungsten, for example.

On the metallization layer 23, the electrical component 24 is arranged via a solder layer (not shown separately). The component 24 has an underside 241 with which the component 24 is arranged on the metallization layer 23, and an upper side 242. The component 24 thus has a thickness given by a distance between the upper side 242 and the underside 241. The upper side 242 and the underside 241 may be metallized (e.g., copper-plated). The electrical component 24 is, for example, a power semiconductor that is configured as a chip.

The ceramic circuit carrier 260 and the electrical component 24 are arranged in a substrate 28 that defines external dimensions of the electrical module 2. In one variant embodiment, the substrate 28 is a potting compound, in which the ceramic circuit carrier 260 and the electrical component 24 are embedded. Alternatively, the substrate 28 is a circuit board, for which case the ceramic circuit carrier 260 and the electrical component 24 have been embedded in a circuit board in a circuit board embedding process.

The substrate 28 includes an upper side that also forms the upper side 21 of the module 2. The underside of the substrate 28 extends flush with the lower metallization layer 27, which forms the underside 22 of the module 2. The ceramic circuit carrier 260 with the lower metallization layer 27 may be connected to a heat sink 7, directly or via a heat-conducting mat not shown. Waste heat of the electrical component 24 is dissipated via the heat sink 7.

The electrical contacts 31, 32, 33 on the upper side 21 of the module are provided by solder pads, also known as solder contacts. The solder pads 31, 32, 33 are electrically connected via solder connections to the solder pads 41, 42, 43 of the circuit board 1. For example, a drain terminal is provided via the solder pad 31, and a source terminal and a gate terminal of the electrical component 24 are provided via the solder pads 32, 33.

Starting from the solder pad 31, vias 5 extend to the upper metallization layer 23 of the ceramic circuit carrier 260. Further, vias 50 extend from the solder pads 32, 23 to the upper side 242 of the electrical component 24. A plated-through hole or via refers to a through hole metallized on the inside.

In each case, a quite large number of vias 5, 50 may be provided, which are arranged one behind the other and are therefore not visible in the sectional view of FIG. 1.

The vias 5, 50 are examined in more detail below. The electrical connection of the electrical component 24 is made by way of the vias 5, 50. The vias 50 are configured as microvias. The vias 50 are produced using a laser process, which contacts the copper-plated upper side of the component 3. The microvias 50 produced are typically completely filled with copper or other metal. This is carried out, for example, in a copper plating process in a copper bath.

The underside potential of the electrical component 24 (e.g., the drain terminal of the electrical component 24), in contrast, is contacted via the upper-side metallization layer 23 of the ceramic circuit carrier 260. Due to the thickness of the electrical component 24, the contact points for the upper-side potentials and the contact point for the underside potential are at different heights.

This provides that the via 5 is to have a significantly greater hole depth. The via 5, in the form of a blind-hole via, for the underside potential, is drilled mechanically. Depending on the thickness of the electrical component 24, diameters larger than 200 μm may be required. Due to the limited capabilities of the circuit board process, these vias cannot be completely filled with copper. It is possible for only the inner walls to be copper-plated. The holes resulting from the vias lead to an undefined outflow of solder in the subsequent soldering process, which affects the solder connection of module 2 to the circuit board 1. The service life of the connection may be significantly reduced as a result. In addition, an outflow of solder may cause air traps. This air volume may expand and contract cyclically under temperature changes during operation and negatively affect the service life of the vias.

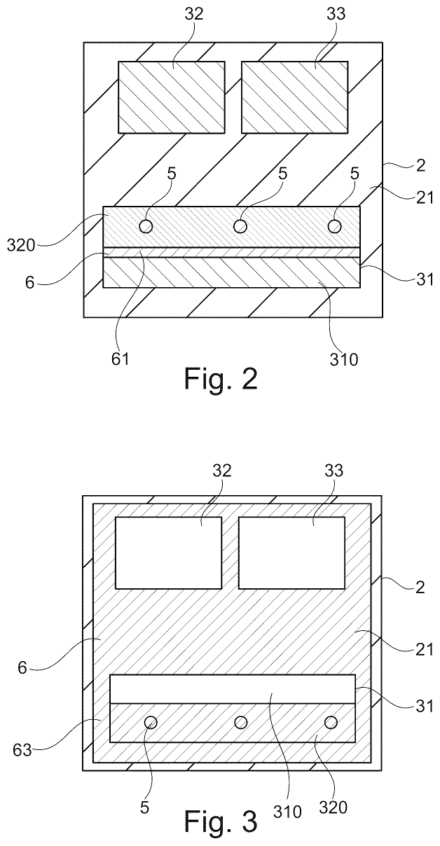

In order to solve these problems, the present embodiments provide for the use of solder resist corresponding to the embodiments of FIGS. 2 to 5.

FIG. 2 shows the electrical module 2 in a view of the upper side 21 from above. On the upper side 21, a solder pad 31 and further solder pads 32, 33 are arranged, in accordance with the explanation for FIG. 1. From the solder pad 31, a plurality of vias 5 arranged in a row extend to the metallization layer 23 of the electrical module 2 (see FIG. 1). The drain terminal of the electrical component 24 is provided by way of the vias 5. The further solder pads 32, 33 also have vias 50 to the upper side 242 of the electrical component 24 (see FIG. 1), which are not shown separately, however.

On the solder pad 31, a strip 61 of solder resist 6 that extends over the entire width of the solder pad 31 constructs a line-shaped barrier, which subdivides the solder pad 31 into a first region 310 and a second region 320. The first region 310 is provided in order that solder may be applied to the first region 310 for the purpose of providing a solder connection between the solder pad 31 and the associated solder pad 41 of the circuit board 1. The second region 320 contains the vias 5. The strip 61 of solder resist 6 prevents solder that is applied to the region 310 from reaching the region 320 and the vias 5. The solder resist 6 thus shields the vias 5 from solder. This eliminates the risk of solder outflow into the vias 5 during the soldering process.

FIG. 3 shows another embodiment, in which solder resist is used for shielding the vias 5. FIG. 3 shows, again, a plan view of the upper side 21 of the electrical module 2, where the solder pads 31, 32, 33 are arranged on the upper side 21 in the same manner as in FIG. 2. In this case, vias 5 are provided in the solder pad 31. In the embodiment of FIG. 3, the upper side 21 of the electrical module 2 is covered with solder resist 6 over the entire surface with the exception of the region of the solder pads 31, 32, 33, where the solder resist forms a surface 63. This surface 63 additionally covers a lower region 320 of the solder pad 31, in which the vias 320 are formed. A further region 310 of the solder pad 31 is not covered with solder resist. This region 310 is used to apply solder thereto for a solder connection.

In the embodiment of FIG. 3, the vias 5 are protected in a particularly effective manner against penetration of solder since the solder resist is also applied over the vias 5.

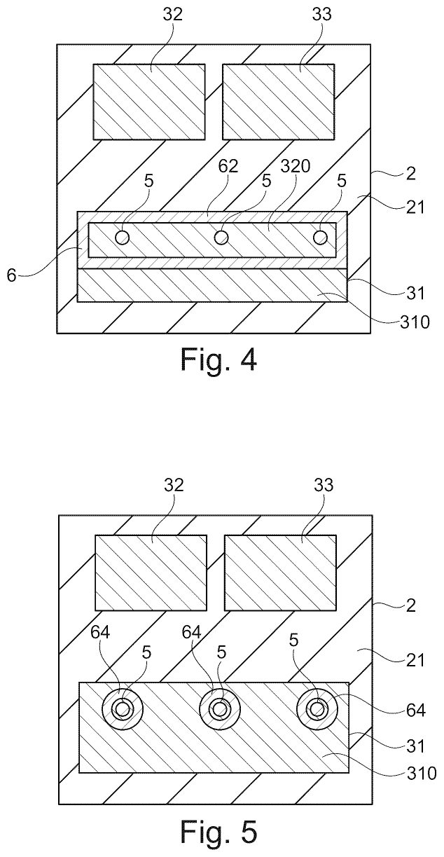

FIG. 4 shows another embodiment with essentially the same structure as in the embodiment of FIG. 2. In the embodiment of FIG. 4, it is provided that the solder resist 6 forms a frame 62 that shields a region 320 of the solder pad 31 surrounding the vias 5 from solder. Thus, the solder pad 31 forms a region 310 on which solder is applied, and the region 320 that is bounded by the frame 62 and is free of solder and protected from solder by the frame 62. The formation of a frame 62 provides that the vias 5 are protected from all sides.

FIG. 5 shows another embodiment with essentially the same structure as in the embodiment of FIG. 2. In the embodiment of FIG. 5, it is provided that each via 5 is individually completely surrounded with solder resist over an angular range of 360°. In this case, rings 64 of solder resist 6 are provided, which extend around the respective vias 5 in a circular manner. Since the solder resist 6 in this embodiment extends only directly adjacent to the vias 5, the region 310, on which solder may be applied, is enlarged compared to the other embodiments.

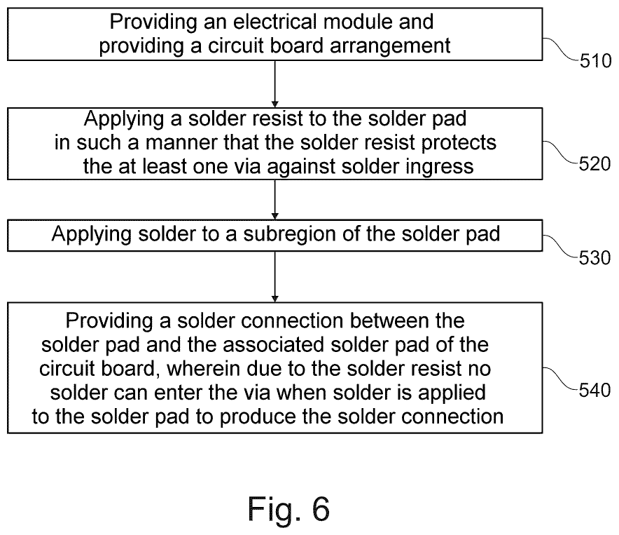

FIG. 6 shows a flowchart for producing a circuit board arrangement according to the present embodiments. In accordance with act 510, an electrical module and a circuit board of the type described are first provided. Then, in act 520, a solder resist is applied to the solder pad. This is carried out such that the solder resist protects the at least one via from the ingress of solder. In variant embodiments of this, the solder may be applied to the solder pad according to FIGS. 2-5.

Then, in act 530, the solder is applied to the solder pad (e.g., to the subregion of the solder pad that is provided for this purpose). No solder is applied to the subregion of the solder pad defined by the solder-resist, which is used to protect the vias.

In addition, according to act 540, a solder connection is provided between the solder pad and the associated solder pad of the circuit board. Due to the solder resist, no solder may enter the vias when solder is applied to the solder pad to produce the solder connection.

The invention is not limited to the embodiments described above, and various modifications and improvements may be made without departing from the concepts described herein. Any of the features described may be used separately or in combination with any other features, provided that they are not mutually exclusive. The disclosure extends to and includes all combinations and sub-combinations of one or a plurality of features that are described here. If ranges are defined, the ranges therefore include all the values within the ranges as well as all the partial ranges that lie within a range.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A circuit board arrangement comprising:
a circuit board that has an upper side and an underside; and
an electrical module having an upper side and an underside, the electrical module being arranged with the upper side of the electrical module on the underside of the circuit board, the electrical module comprising:
a solder pad arranged on the upper side of the electrical module, the solder pad being in electrical contact via a solder layer with an associated solder pad of the circuit board;
a metallization layer located at a distance from the upper side of the electrical module;
an electrical component that is arranged on the metallization layer and is electrically connected to the metallization layer; and
at least one via extending from the solder pad on the upper side of the electrical module up to the metallization layer,
wherein a solder resist is partially arranged on the solder pad such that the at least one via, applied to the solder pad, is shielded from the solder.

2. The circuit board arrangement of claim 1, wherein the solder resist is arranged as a strip on the solder pad,
wherein the strip made of the solder resist extends over an entire width of the solder pad and subdivides the solder pad into two regions, a first region of the two regions being a region on which the solder is applied, and a second region of the two regions being free of solder, and
wherein the at least one via is formed in the second region.

3. The circuit board arrangement of claim 1, wherein the solder resist is arranged along a frame on the solder pad, which surrounds the at least one via,
wherein the frame of solder resist subdivides the solder pad into two regions, a first region of the two regions being a region to which solder is applied and a second region of the two regions being free of solder, and
wherein the at least one via is formed in the second region.

4. The circuit board arrangement of claim 1, wherein the solder resist is formed over an entire surface of the upper side of the electrical module, with the exception of certain regions on which the surface has the solder pad and further solder pads, and
wherein the solder resist covers the solder pad in a region of the at least one via.

5. The circuit board arrangement of claim 1, wherein each via of the at least one via is surrounded by solder resist over an angular range of 360°.

6. The circuit board arrangement of claim 5, wherein the solder resist is arranged on the solder pad around the respective via in a circular manner.

7. The circuit board arrangement of claim 1, wherein the solder pad is rectangular.

8. The circuit board arrangement of claim 1, wherein the electrical component has a high-voltage potential applied to an underside of the electrical component via the at least one via and the metallization layer.

9. The circuit board arrangement of claim 1, wherein the electrical component is a semiconductor component.

10. The circuit board arrangement of claim 9, wherein the semiconductor component is a power semiconductor.

11. The circuit board arrangement of claim 1, wherein the electrical module further comprises:
a ceramic circuit carrier having an insulating ceramic layer, the metallization layer being arranged on an upper side of the insulating ceramic layer; and
further solder pads that are arranged on the upper side of the electrical module and are used for contacting contacts on an upper side of the electrical component.

12. A method for producing a circuit board arrangement that comprises a circuit board that has an upper side and an underside, and an electrical module having an upper side and an underside that is arranged with the upper side of the electrical module on the underside of the circuit board, the electrical module comprising a solder pad arranged on the upper side of the electrical module, which is in electrical contact via a solder layer with an associated solder pad of the circuit board, a metallization layer located at a distance from the upper side of the electrical module, an electrical component that is arranged on the metallization layer and is electrically connected to the metallization layer, and at least one via extending from the solder pad on the upper side of the electrical module up to the metallization layer, the method comprising:
providing the electrical module;
providing the circuit board;
applying a solder resist to the solder pad such that the solder resist protects the at least one via against ingress of the solder;
applying solder to a subregion of the solder pad; and
providing a solder connection between the solder pad and the associated solder pad of the circuit board,
wherein, due to the solder resist, no solder enters the at least one via when solder is applied to the solder pad for producing the solder connection.

13. The method of claim 12, wherein the solder resist subdivides the solder pad into different regions.

14. The method of claim 12, wherein the solder resist is applied as a strip on the solder pad and extends along an entire width of the solder pad.

15. The method of claim 12, wherein the solder resist is applied on the solder pad along a frame that surrounds the at least one via.

16. The method of claim 12, wherein the solder resist is formed over an entire surface of the upper side of the electrical module, with the exception of certain regions on which the surface comprises the solder pad and further solder pads, and
wherein the solder resist covers the solder pad a in a region of the at least one via.

17. The method of claim 12, wherein each via of the at least one via is surrounded by solder resist over an angular range of 360°.

18. The method of claim 17, wherein the solder resist is arranged on the solder pad around the respective via in a circular manner.
